(19) United States
(12) Patent Application Publication
(10) Pub. No.: US 2005/0112841 A1
(43) Pub. Date: May 26, 2005

(54) Method for isolating semiconductor devices

(75) Inventor: Jae-Eun Lim, Ichon-shi (KR)

Correspondence Address: Finnegan, Henderson, Farabow,;Garrett & Dunner, L.L.P., 1300 I Street, N.W., Washington, DC, 20005-3315, US

(73) Assignee: HYNIX SEMICONDUCTOR INC.

(21) Appl. No.: 10/872,436

(22) Filed: Jun. 22, 2004

(30) Foreign Application Priority Data
Nov. 24, 2003 (KR) 2003-83579

(51) Int. Cl. H01L 21/336

(52) U.S. Cl. 438/424

(57) ABSTRACT

Disclosed is a method for isolating semiconductor devices. The method includes the steps of: forming a semi-finished substrate provided with a trench and a patterned pad nitride layer on a substrate; forming a first oxide layer on at least one portion of the trench; forming a second oxide layer on the first oxide layer and the patterned pad nitride layer; forming a nitride layer on the second oxide layer; forming an isolation oxide layer on the second oxide layer; and etching the isolation oxide layer, wherein the second oxide layer serves as an etch stop for the nitride layer.

### FIELD OF THE INVENTION

The present invention relates to a semiconductor device; and, more particularly, to a method for isolating semiconductor devices with use of a shallow trench isolation (STI) method.

### DESCRIPTION OF RELATED ARTS

As known, a device isolation technology has been employed to electrically isolate individual devices such as transistors and capacitors during fabrication of a semiconductor integration circuit. Among various methods of the device isolation technology, a local oxidation of silicon (LOCOS) method and a shallow trench isolation (STI) method have been commonly adopted.

The LOCOS method forms a nitride layer-based mask pattern on an active region of a silicon substrate and thermally oxidizing the silicon substrate with use of the mask pattern as a mask. However, the LOCOS method has disadvantages that an oxide layer is formed in a wide area and a bird's beak phenomenon occurs at an interface surface between the oxide layer and the silicon substrate. Thus, it is limited to apply the LOCOS method to highly integrated devices. As a result of this limitation, the STI method is more widely employed in highly integrated devices since the STI method forms a device isolation region by forming a shallow trench in a substrate and then burying an oxide layer into the trench.

FIGS. 1A to 1C are cross-sectional views for illustrating a method for isolating semiconductor devices through performing a conventional STI method.

Referring to FIG. 1A, a pad oxide layer 11 and a pad nitride layer 12 are sequentially deposited on a substrate 10 made of a material such as silicon. The pad nitride layer 12 and the pad oxide layer 11 are patterned by performing an etching process with use of a device isolation mask. From this etching process, a device isolation region of the substrate 10 is exposed. Herein, the pad oxide layer 11 functions as a buffer layer for blocking an exertion of stress caused by a direct contact between the substrate 10 and the pad nitride layer 12. The pad nitride layer 12 functions as an etch mask for forming a trench and an etch stop layer during a chemical mechanical polishing (CMP) process.

Next, an exposed portion of the substrate 10 is etched to a predetermined thickness to thereby form a trench. Then, an oxide layer 13 is formed on sidewalls of the trench. Thereafter, a nitride layer 14 is formed on an entire surface of the above resulting structure. Herein, the nitride layer 14 is formed to improve device characteristics by suppressing a boron segregation phenomenon. After the formation of the nitride layer 14, a device isolation oxide layer 15 is deposited on the above substrate structure including the nitride layer 14, thereby completely filling the trench.

Referring to FIG. 1B, a CMP process is performed to the device isolation oxide layer 15 until a surface of the pad nitride layer 12 is exposed.

Referring to FIG. 1C, the pad nitride layer 12 is removed by a wet etching process, and concurrently, upper portions of the nitride layer 14 are etched unintentionally.

Although the nitride layer 14 is formed on the sidewalls of the trench for improving device characteristics, the upper portions of the nitride layer 14 are lost during the wet etching of the pad nitride layer 12. Thus, the device isolation oxide layer 15 is also damaged at a boundary region of an active region, resulting in generation of moats as shown in FIG. 1C.

FIG. 2 is a detailed diagram showing the above mentioned moat generation. As shown, a wet etching process proceeds after a substrate structure including a substrate 210, a pad oxide layer 211, an oxide layer 212, a pad nitride layer 213, a nitride layer 215 and a device isolation oxide layer 216 is planarized. However, when the pad nitride layer 213 is etched by a wet etching process, one side of the upper portion of the nitride layer 215 is almost entirely exposed, thereby being more susceptible to the wet etching process. Thus, during the wet etching process, the exposed portion of the nitride layer 215 is also etched. The etched nitride layer 215 is denoted with the reference number 215A.

As a result of this extended etching, depths of the generated moats become much deeper, causing an electric field to be concentrated in one region and remnants to remain during subsequent processes for forming word lines and so on. These remnants cause bridge formation.

Furthermore, in a highly integrated semiconductor device, variations in a threshold voltage of a transistor extend greatly depending on a size of a moat because the size of an active region becomes reduced in proportion to the size of a moat. If a dose of ion implantation for controlling the threshold voltage is increased in order to compensate the threshold voltage, there may be a problem of an increased channel resistance. Eventually, the moat generated in the course of performing the STI process becomes a critical factor for degrading device characteristics.

Also, in a dynamic random access memory (DRAM) device, large-scale of integration leads the size of a device isolation region to be gradually decreased. For instance, in about 80 nm technology, the size of the device isolation region is decreased to about 0.12 μm. This decrease in the device isolation region leads to a trend that sidewalls of a trench become thicker while bottom corners of the trench become thinner due to a mechanical stress regionally created in the trench. This trend is shown in FIG. 3A.

This differentiated thickness of the trench is observed since the growth rate of the bottom portion of the oxide layer is different from that of the side portions of the oxide layer during the formation of the oxide layer by a furnace oxidation process.

Also, as the size of the device isolation region decreases, the oxide layer is more likely grown locally. Thus, the stress created by this growth rate difference is not released but superimposed, resulting in an increased exertion of the stress.

FIG. 3B is a diagram for depicting a problem of a pronounced thickness difference between a sidewall 33A and a bottom portion 33B of an oxide layer 33. In case of applying this STI method to a P-channel metal oxide semiconductor field effect transistor (MOSFET), the thickness difference between the sidewall 33A and the bottom portion 33B of the oxide layer 33 disposed within a trench may induce a failure in obtaining an appropriate break down voltage level of a device isolation layer. Also, this thickness difference may become a factor for decreasing a gap-fill margin of a device isolation layer.

### SUMMARY OF THE INVENTION

It is, therefore, an object of the present invention to provide a method for isolating devices in a semiconductor device capable of preventing a moat from being generated at a boundary region between a device isolation layer and an active region during the application of a shallow trench isolation (STI) method.

It is another object of the present invention to provide a method for isolating semiconductor devices capable of minimizing a thickness difference between a sidewall and a bottom surface of a lateral oxide layer when a device isolation layer is formed by employing a STI method.

In accordance with an aspect of the present invention, there is provided a method for isolating semiconductor devices, including the steps of: forming a semi-finished substrate provided with a trench and a patterned pad nitride layer on a substrate; forming a first oxide layer on at least one portion of the trench; forming a second oxide layer on the first oxide layer and the patterned pad nitride layer; forming a nitride layer on the second oxide layer; forming an isolation oxide layer on the second oxide layer; and etching the isolation oxide layer, wherein the second oxide layer serves as an etch stop for the nitride layer.

In accordance with another aspect of the present invention, there is also provided a method for isolating semiconductor devices, including the steps of: forming a trench in a substrate; forming and a patterned pad nitride layer on top of the substrate except for the trench; forming a first oxide layer on the trench; forming a second oxide layer on the patterned pad nitride layer and the first oxide layer; forming a nitride layer on the second oxide layer; filling an isolation oxide layer into the trench; planarizing the isolation layer by using a chemical mechanical polishing process until the patterned pad nitride layer is exposed; and removing the patterned pad nitride layer.

In accordance with still another aspect of the present invention, there is also provided a semiconductor device, including: a substrate provided with a trench; a first oxide layer formed within the trench; a second oxide layer deposited on the first oxide layer; a nitride layer formed on the second oxide layer; and an isolation layer filled into the trench.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1C are cross-sectional views for describing a conventional method for isolating semiconductor devices;

FIG. 2 is a detailed diagram showing generation of moats during the application of a conventional shallow trench isolation (STI) method;

FIG. 3A is a graph showing a trend that a thickness difference between a sidewall and a bottom portion of a lateral oxide layer disposed within a trench is increasingly pronounced as the scale of integration increases;

FIG. 3B is a diagram showing a problem of a pronounced thickness difference between a sidewall and a bottom portion of a lateral oxide layer disposed within a trench;

FIG. 4 is a diagram showing how a moat generation is impeded in accordance with a preferred embodiment of the present invention; and

FIGS. 5A to 5F are cross-sectional views for illustrating a method for isolating semiconductor devices in accordance with the preferred embodiment of the present invention.

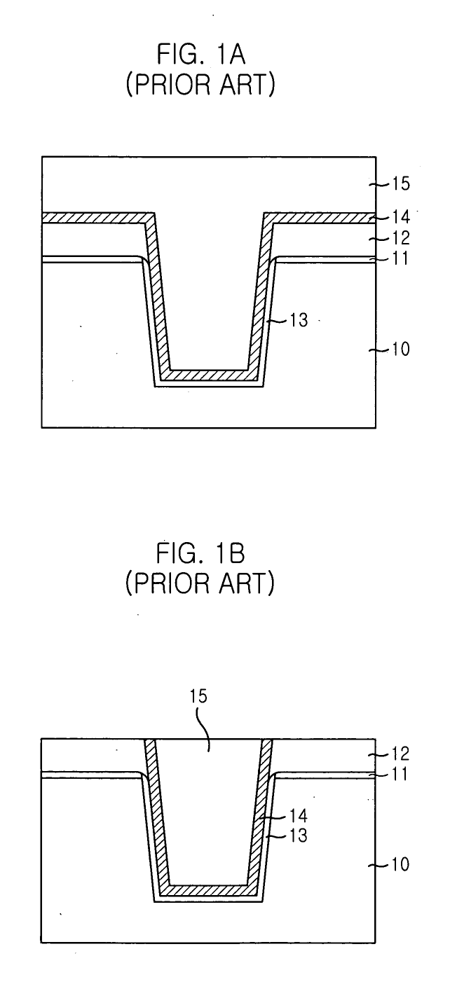

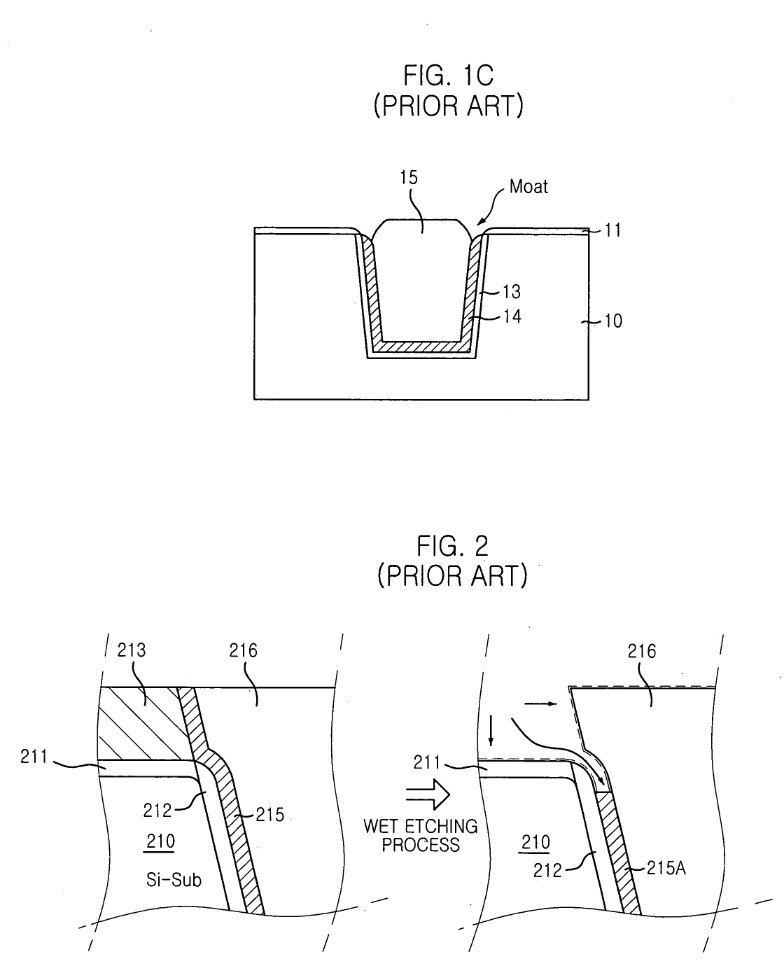

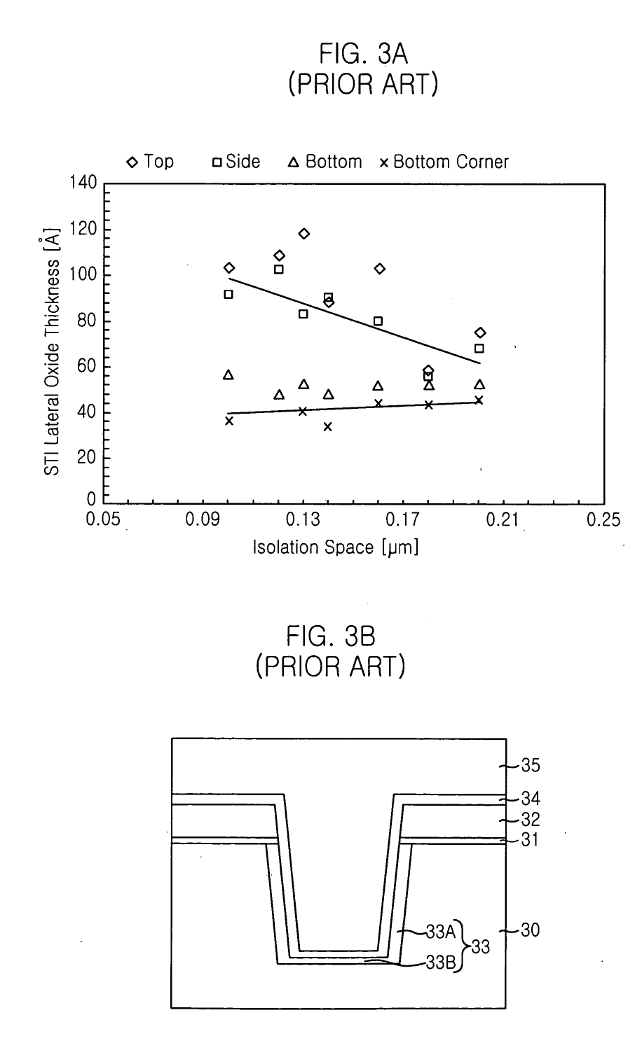

### DETAILED DESCRIPTION OF THE INVENTION

Hereinafter, a method for isolating semiconductor devices in accordance with preferred embodiments of the present invention will be described in detail with reference to the accompanying drawings.

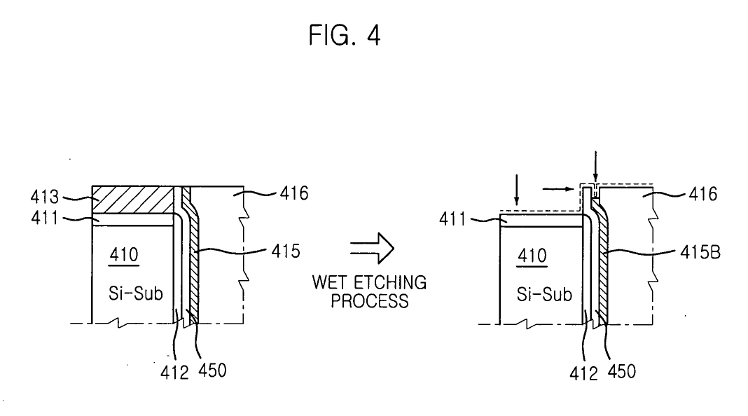

FIG. 4 is a diagram showing how a moat generation is impeded in accordance with a preferred embodiment of the present invention.

In comparison with FIG. 2, a second oxide layer 450 is formed on a profile containing a pad nitride layer 413 and a first oxide layer 412 through employing a chemical vapor deposition (CVD) method. This second oxide layer 450 plays a role in reducing losses of the nitride layer 415 when a wet etching process is performed for removing the pad nitride layer 413. That is, the second oxide layer 450 serves as an etch stop for a nitride layer 415. Herein, the nitride layer obtained after the wet etching process is denoted with the reference number 415B. Because of this additional second oxide layer 450, it is possible to impede the moat generation.

As shown above, the finally obtained oxide layer is formed in two steps. In the first step, a first oxide layer, which is the first oxide layer 412 in FIG. 4, is formed by an oxidation process. Then, in the second step, a second oxide layer, i.e., the second oxide layer 450 in this preferred embodiment, is formed by employing a specific deposition method.

There are advantages if the oxide layer is formed in two steps. Firstly, it is possible to decrease a thickness of the first oxide layer grown through the oxidation process. Thus, a mechanical stress created from bottom edge portions of a trench during a thermal oxidation process can be reduced. This decrease in the mechanical stress provides an advantage in junction leakage.

Secondly, the decrease in the thickness of the first oxide layer grown through the oxidation process makes it possible to secure the larger active region. Since the oxidation process makes oxygen diffused into a substrate and an oxide layer is grown on the substrate, the area of the active region becomes smaller as the thickness of the oxide layer increases. Also, the smaller reduction in the area of the active region improves a refresh characteristic and yields of dynamic random access memory (DRAM) devices. Eventually, the above described method of forming the oxide layer in two steps is applicable to highly integrated devices as well.

Thirdly, as described above, the first oxide layer is formed to have a thinner thickness by the oxidation process, and then, the second oxide layer is formed to have the rest thickness of the total intended thickness of the oxide layer by the deposition process, e.g., the CVD method. This approach makes it possible to have the oxide layer with a consistent thickness within the trench. More specifically, the conventionally adopted oxidation process adversely induces a mechanical stress and inconsistency in the thickness of the oxide layer since the oxidation process forms the oxide layer by diffusion of oxygen into the substrate. In contrast, the CVD method used for forming the second oxide layer is free from the mechanical stress since the CVD method deposits the oxide layer on the substrate. Thus, the CVD deposition method makes it possible to obtain the consistent thickness of the oxide layer. If the oxide layer is formed with the consistent thickness, it is possible to increase a margin for gap-filling a trench with a device isolation oxide layer. Also, in case of the above described device isolation method is applied to a P-channel metal oxide semiconductor field effect transistor (MOSFET), the consistent thickness of the oxide layer provides an effect of preventing a failure in obtaining an appropriate break down voltage level of the device isolation oxide layer.

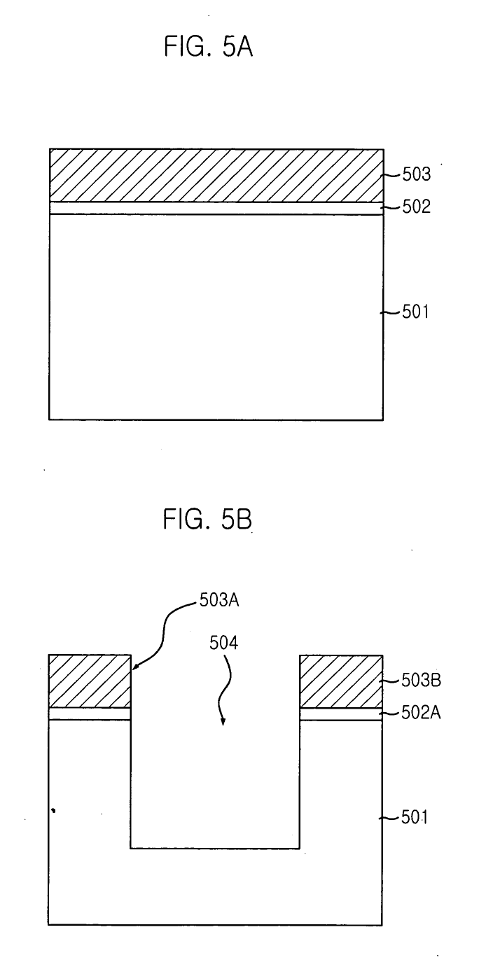

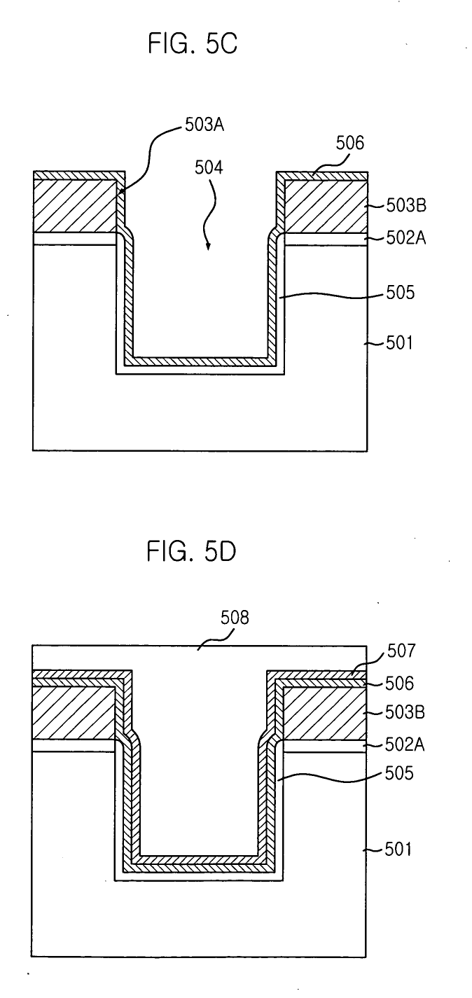

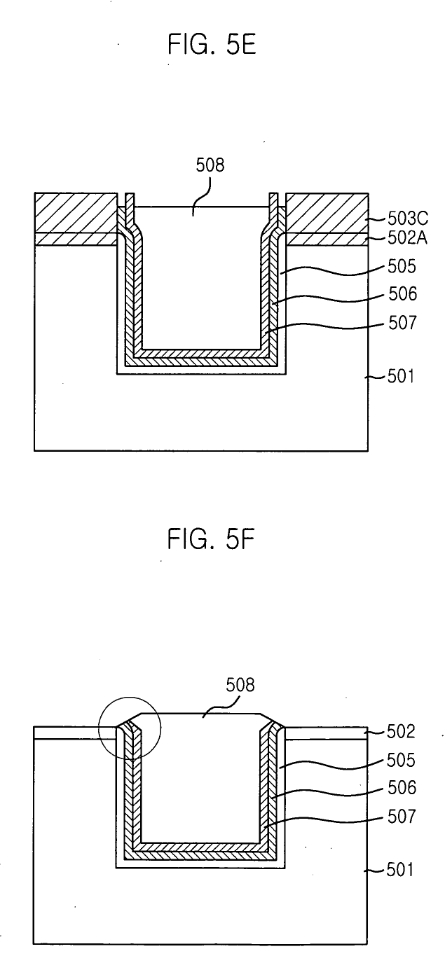

FIGS. 5A to 5F are cross-sectional views describing a method for isolating semiconductor devices in accordance with the preferred embodiment of the present invention.

Referring to FIG. 5A, a buffer oxide layer 502 and a pad nitride layer 503 are formed on a substrate 501, made of a material such as silicon, in order to serve as an etch mask during a following etching process of forming a trench and an etch stop layer during a chemical mechanical polishing (CMP) process. At this time, the buffer oxide layer 502 has a thickness ranging from approximately 50 Å to approximately 100 Å, while the pad nitride layer 503 has a thickness ranging from about 500 Å to about 700 Å.

The buffer oxide layer 502 plays a role in blocking generation of a stress caused by a direct contact between the substrate 501 and the pad nitride layer 503. Although the preferred embodiment exemplifies the buffer oxide layer 502 formed in a single layer, it is possible to form a stack of layers of polysilicon and oxide and an oxynitride layer for the same purpose. Also, the formation of the buffer oxide layer 502 can be omitted. The substrate 501 can be formed of silicon or other semiconducting compounds.

Referring to FIG. 5B, the pad nitride layer 503 and the buffer oxide layer 502 are first etched by performing a lithography process along with use of a device isolation mask. After the lithography process, a patterned pad nitride layer 503B and a patterned buffer oxide layer 502A are formed. Then, a portion of the substrate 501 is etched by using the patterned pad nitride layer 503B as an etch mask, so that a trench 504 is formed. The patterned pad nitride layer 503B has sidewalls 503A at an opened region.

More specifically, a photoresist is formed on the pad nitride layer 503, and a photo-exposure and developing process is performed by using the device isolation mask to thereby form a photoresist pattern. Then, the pad nitride layer 503 and the buffer oxide layer 502 are etched with use of the photoresist pattern as an etch mask, and the portion of the substrate 501 is continuously etched with use of the patterned pad nitride layer 503B as an etch mask. Thereafter, the remaining photoresist pattern is removed.

Referring to FIG. 5C, a first oxide layer 505 is formed through performing an oxidation process to the trench 504. Subsequent to the formation of the first oxide layer 505, a second oxide layer 506 is formed through a deposition method. It is preferable to form the first oxide layer 505 as thin as possible in order to achieve an effect of blocking an active region from being reduced. However, it is required to form the first oxide layer 505 with a minimum thickness to secure a characteristic of an interface between the silicon and the silicon oxide. That is, the first oxide layer 505 is required to have the minimum thickness to block formation of unstable dangling bonds between the silicon and the silicon dioxide and thus to obtain the stably formed interface. Even though the minimum thickness of the first oxide layer 505 varies depending on the design rule, the minimum thickness preferably ranges from approximately 10 Å to approximately 40 Å.

The oxidation process for forming the first oxide layer 505 can be a method such as a furnace oxidation method, a rapid thermal oxidation (RTO) method or the like. The furnace oxidation is much preferable though. In more detail of the furnace oxidation method, chloride (Cl) gas may be added with a quantity less than about 10% in the beginning of the oxidation process in order to minimize the trap site in the interface between the substrate 501 and the first oxide layer 505. Preferably, a dry oxidation process proceeds at a temperature ranging from approximately 750° C. to approximately 900° C. to thereby prevent the generation of an interface trap.

In the oxidation process for forming the first oxide layer 505, the first oxide layer 505 is not formed on an exposed surface of the patterned pad nitride layer 503B and the sidewalls 503A. Even if the first oxide layer 505 is formed on such undesired areas, the thickness of the first oxide layer 505 is thin enough to be negligible.

A second oxide layer 506 is formed on the above resulting structure including the first oxide layer 505 by employing a method such as a CVD. Herein, the CVD method deposits the second oxide layer 506 even on the exposed surface of the patterned pad nitride layer 503B and the sidewalls 503A. At this time, the second oxide layer 506 is formed to have a thickness that gives the total thickness of the whole oxide layer with the addition of the already decided thickness of the first oxide layer 505. Although the thickness of the second oxide layer 506 varies depending on the design rule, the thickness preferably ranges from approximately 10 Å to approximately 100 Å.

As described above, since the second oxide layer 506 is formed even on the sidewalls 503A of the patterned pad nitride layer 503B, it is possible to prevent losses of a nitride layer during the succeeding processes. As a result of this effect, it is further possible to prevent generation of moats. Also, compared to the conventionally employed oxidation process, e.g., a furnace oxidation, the use of the CVD method makes it possible to form the second oxide layer 506 uniformly on sidewalls and a bottom surface of the trench 504.

Referring to FIG. 5D, a nitride layer 507 is deposited along a profile containing the second oxide layer 506 until reaching a thickness ranging from approximately 30 Å to approximately 70 Å. Then, a device isolation oxide layer 508 is formed on the nitride layer 507, thereby filling the trench 504. Particularly, it is preferable to form the device isolation oxide layer 508 by employing a method such as a high density plasma (HDP) deposition method, which provides a good gap-fill property through repeatedly performing the step of alternately depositing and sputtering the oxide layer.

Referring to FIG. 5E, the device isolation oxide layer 508 is subjected to a CMP process until a surface of the patterned pad nitride layer 503B is exposed. Preferably, a portion of the patterned pad nitride layer 503B is also etched during the CMP process, so that the second oxide layer 506 does not remain on the surface of the patterned pad nitride layer 503B. That is, if the thickness of the patterned pad nitride layer 503B is approximately 600 Å, the planarized pad nitride layer 503C has a thickness ranging from approximately 450 Å to approximately 550 Å.

Referring to FIG. 5F, the planarized pad nitride layer 503C is etched away by dipping the above substrate structure into a wet etching solution for removing a nitride layer, e.g., phosphoric acid (H₃PO₄). For the above wet etching process, buffered oxide etchant (BOE) is firstly used to remove the oxide layer, e.g., the second oxide layer 506, which might remain on the planarized pad nitride layer 503C. Subsequently, H₃PO₄ is used to remove the planarized pad nitride layer 503C.

In accordance with the preferred embodiment of the present invention, it is possible to prevent generation of moats at an interface between the device isolation region and the active region when the device isolation layer is formed through the use of a STI method. This prevention of the moat generation further provides effects of obtaining a threshold voltage without increasing a dose of implanting ions for controlling the threshold voltage and of improving functions of transistors. In particular, in case of applying the STI method for isolating cells in a DRAM device, a threshold voltage for each transistor in a cell array region is consistently distributed.

Also, since the larger active region can be secured on the basis of the preferred embodiment, it is possible to improve a refresh characteristic and yields of DRAM devices. In addition, the formation of the oxide layer in two steps by employing the oxidation process and the CVD process provides an effect on consistency in the thickness of the oxide layer distributed within the trench. Thus, it is possible to increase a gap-fill margin for the device isolation layer and prevent a failure in obtaining an appropriate break down voltage level of the device isolation layer.

The present application contains subject matter related to the Korean patent application No. KR 2003-0083579, filed in the Korean Patent Office on Nov. 24, 2003, the entire contents of which being incorporated herein by reference.

While the present invention has been described with respect to certain preferred embodiments, it will be apparent to those skilled in the art that various changes and modifications may be made without departing from the spirit and scope and spirit of the invention as defined in the following claims.

1. A method for isolating semiconductor devices, comprising the steps of:
forming a semi-finished substrate provided with a trench and a patterned pad nitride layer on a substrate;
forming a first oxide layer on at least one portion of the trench;
forming a second oxide layer on the first oxide layer and the patterned pad nitride layer;
forming a nitride layer on the second oxide layer; forming an isolation oxide layer on the second oxide layer; and
etching the isolation oxide layer, wherein the second oxide layer serves as an etch stop for the nitride layer.

2. The method of claim 1, wherein the second oxide layer is formed on the first oxide layer and between sidewalls of the patterned pad nitride layer and the nitride layer.

3. The method of claim 1, wherein the second oxide layer is formed by employing a chemical vapor deposition (CVD) method.

4. The method of claim 1, wherein the first oxide layer is formed by employing one of a furnace oxidation method and a rapid thermal oxidation method.

5. The method of claim 4, wherein the first oxide layer is formed with a minimum thickness to secure an interface characteristic.

6. The method of claim 4, wherein the furnace oxidation process employs chloride (Cl) gas in an initial stage of the furnace oxidation process to minimize the trap site in the interface between the substrate and the first oxide layer.

7. The method of claim 4, wherein the first oxide layer has a thickness ranging from approximately 10 Å to approximately 40 Å.

8. The method of claim 4, wherein the second oxide layer has a thickness ranging from approximately 10 Å to approximately 100 Å.

9. The method of claim 4, wherein the nitride layer has a thickness ranging from approximately 30 Å to approximately 70 Å.

10. The method of claim 1, wherein the second oxide layer is formed by employing a deposition process to obtain consistency in a thickness of an oxide layer including the first oxide layer and the second oxide layer.

11. The method of claim 1, further comprising a pad oxide layer formed below the pad nitride layer as a buffer layer.

12. A method for isolating semiconductor devices, comprising the steps of:
forming a trench in a substrate;
forming and a patterned pad nitride layer on top of the substrate except for the trench;
forming a first oxide layer on the trench;
forming a second oxide layer on the patterned pad nitride layer and the first oxide layer;
forming a nitride layer on the second oxide layer;
filling an isolation oxide layer into the trench;
planarizing the isolation layer by using a chemical mechanical polishing process until the patterned pad nitride layer is exposed; and
removing the patterned pad nitride layer.

13. The method of claim 12, wherein the first oxide layer is formed by one of a furnace oxidation method and a rapid thermal oxidation method and the second oxide layer is formed by a chemical vapor deposition process.

14. The method of claim 12, wherein the first oxide layer is formed with a minimum thickness to secure an interface characteristic.

15. The method of claim 12, wherein the CMP process is performed under a target that a portion of the patterned pad nitride layer is etched to block the first and the second oxide layers from remaining on the patterned pad nitride layer.

16. The method of claim 12, wherein the patterned pad nitride layer is etched by dipping the substrate structure planarized after the CMP process into a chemical solution of phosphoric acid (H₃PO₄)

17. The method of claim 16, wherein prior to etching the patterned pad nitride layer, the planarized substrate structure is dipped into a chemical solution of buffered oxide etchant (BOE) to remove the remaining first and second oxide layers.

18. A semiconductor device, comprising:
a substrate provided with a trench;
a first oxide layer formed within the trench;
a second oxide layer deposited on the first oxide layer;
a nitride layer formed on the second oxide layer; and
an isolation layer filled into the trench.

19. The semiconductor device of claim 18, wherein the oxide layer is formed by a furnace oxidation process.

20. The semiconductor device of claim 18, wherein the second oxide layer is formed by a chemical vapor deposition process.

21. The semiconductor device of claim 18, wherein the first oxide layer has a thickness ranging from approximately 10 Å to approximately 40 Å.

22. The semiconductor device of claim 18, wherein the second oxide layer has a thickness ranging from approximately 10 Å to approximately 100 Å.

23. The semiconductor device of claim 18, wherein the nitride layer has a thickness ranging from approximately 30 Å to approximately 70 Å.
